(19) United States
(12) Patent Application Publication
(10) Pub. No.: US 2010/0151385 A1
(43) Pub. Date: Jun. 17, 2010

(54) STACK OF NEGATIVE-WORKING IMAGEABLE ELEMENTS

(76) Inventors: Kevin B. Ray, Hudson, NH (US); James L. Mulligan, Fort Collins, CO (US); Scott A. Beckley, Windsor, CO (US)

Correspondence Address: EASTMAN KODAK COMPANY;PATENT LEGAL STAFF, 343 STATE STREET, ROCHESTER, NY, 14650-2201, US

(21) Appl. No.: 12/336,635

(22) Filed: Dec. 17, 2008

(51) Int. Cl. G03F 7/004

(52) U.S. Cl. 430/273.1; 430/270.1

(57) ABSTRACT

A plurality of negative-working lithographic printing plate precursors is provided in a stack. Each precursor comprises an aluminum-containing substrate having thereon a single imageable layer and an outermost topcoat that has a dry coating weight equal to or less than 1 g/m². The non-imaging backside of the substrate is free of polymer coatings and has an average surface roughness (Ra) in both longitudinal and width directions greater than 0.15 μm. In addition, the imageable side of each underlying precursor is arranged in direct contact with the aluminum-containing substrate of the precursor above it without the use of an interleaf paper between the precursors.

### FIELD OF THE INVENTION

This invention relates to stacks of negative-working lithographic printing plate precursors that are provided for shipping, storage, or use without interleaf papers between the precursors.

### BACKGROUND OF THE INVENTION

Radiation-sensitive compositions are routinely used in the preparation of imageable materials including lithographic printing plate precursors. Such compositions generally include a radiation-sensitive component, an initiator system, and a binder, each of which has been the focus of research to provide various improvements in physical properties, imaging performance, and image characteristics.

Recent developments in the field of printing plate precursors concern the use of radiation-sensitive compositions that can be imaged by means of lasers or laser diodes, and more particularly, that can be imaged and/or developed on-press. Laser exposure does not require conventional silver halide graphic arts films as intermediate information carriers (or “masks”) since the lasers can be controlled directly by computers. High-performance lasers or laser-diodes that are used in commercially-available image-setters generally emit radiation having a wavelength of at least 700 nm, and thus the radiation-sensitive compositions are required to be sensitive in the near-infrared or infrared region of the electromagnetic spectrum. However, other useful radiation-sensitive compositions are designed for imaging with ultraviolet or visible radiation.

There are two possible ways of using radiation-sensitive compositions for the preparation of printing plates. For negative-working printing plates, exposed regions in the radiation-sensitive compositions are hardened and unexposed regions are washed off during development. For positive-working printing plates, the exposed regions are dissolved in a developer and the unexposed regions become an image.

Various negative-working radiation compositions and imageable elements are described in and U.S. Pat. No. 6,309,792 (Hauck et al.), U.S. Pat. No. 6,569,603 (Furukawa), U.S. Pat. No. 6,893,797 (Munnelly et al.), U.S. Pat. No. 6,787,281 (Tao et al.), and U.S. Pat. No. 6,899,994 (Huang et al.), U.S. Patent Application Publications 2003/0118939 (West et al.), 2005/0008971 (Mitsumoto et al.), and 2005/0204943 (Makino et al.), and EP 1,079,276A (Lifka et al.), EP 1,182,033A (Fujimaki et al.), and EP 1,449,650A (Goto).

Usually lithographic printing plate precursors are supplied to customers in a stack of multiple elements, usually several hundred elements, with interleaf (or slip sheet) papers between adjacent precursors to prevent adhesion to one another and scratches on the imageable side. Without such interleaf papers, damage to the imageable side may occur during factory finishing operations, transportation, storage, or during use in plate setter devices.

There has been a desire to eliminate the use of interleaf paper to reduce waste and to simplify the loading process into imaging devices. One approach for doing this is described in EP 1,865,380 (Endo) in which silica-coated polymer particles are added to the topcoat. Organic filler particles are used in a similar manner in the materials of EP 1,839,853 (Yanaka et al.).

### SUMMARY OF THE INVENTION

This invention provides a stack comprising a plurality of negative-working lithographic printing plate precursors wherein each precursor comprises an aluminum-containing substrate having thereon a single imageable layer and an outermost topcoat that has a dry coating weight equal to or less than 1 g/m²,

wherein the non-imaging backside of the substrate is free of polymer coatings and has an average surface roughness (Ra) in both longitudinal and width directions greater than 0.15 μm, and wherein the imageable side of each underlying precursor is arranged in direct contact with the aluminum-containing substrate of the precursor above it, without the use of an interleaf paper between the precursors.

We have discovered a way to eliminate the use of interleaf paper and avoids the use of particulate materials in the outermost topcoat. We have found that interleaf papers can be avoided in stacks of lithographic printing plate precursors if each precursor has a topcoat that has a dry coating weight of 1 g/m² or less. This invention also avoids using polymer coatings on the backside of the aluminum-containing substrate.

### DETAILED DESCRIPTION OF THE INVENTION

Unless the context indicates otherwise, when used herein, the terms “negative-working lithographic printing plate precursor”, and “printing plate precursor” are meant to be references to embodiments useful in the stacks of the present invention.

In addition, unless the context indicates otherwise, the various components described herein such as “polymeric binder”, “free radically polymerizable component”, “radiation absorbing compound”, and similar terms also refer to mixtures of such components. Thus, the use of the articles “a”, “an”, and “the” is not necessarily meant to refer to only a single component.

Moreover, unless otherwise indicated, percentages refer to percents by dry weight.

For clarification of definitions for any terms relating to polymers, reference should be made to “Glossary of Basic Terms in Polymer Science” as published by the International Union of Pure and Applied Chemistry (“IUPAC”), Pure Appl. Chem. 68, 2287-2311 (1996). However, any definitions explicitly set forth herein should be regarded as controlling.

The term “polymer” refers to high and low molecular weight polymers including oligomers, homopolymers, and copolymers.

The term “copolymer” refers to polymers that are derived from two or more different monomers.

The term “backbone” refers to the chain of atoms (carbon or heteroatoms) in a polymer to which a plurality of pendant groups are attached. One example of such a backbone is an “all carbon” backbone obtained from the polymerization of one or more ethylenically unsaturated polymerizable monomers. However, other backbones can include heteroatoms wherein the polymer is formed by a condensation reaction or some other means.

The negative-working lithographic printing plate precursors used in the practice of this invention can be any desired configuration, composition, substrate, and layer construction as long as the outermost topcoat has the desired dry coverage described herein. For example, these precursors can be sensitive to imaging radiation within the wide range of from about 250 to about 1400 nm, but they are more likely sensitive to imaging radiation of either from about 250 to about 450 nm or from about 700 to about 1400 nm.

In addition, each lithographic printing plate precursors can be on-press developable, or designed for development off-press. Some of the on-press developable precursors have an imageable layer comprising a polymeric binder that has a backbone to which are attached pendant poly(alkylene oxide) side chains, cyano groups, or both, and is optionally present in the form of discrete particles.

In the lithographic printing plate precursors, there is an aluminum-containing substrate having disposed thereon a single imageable layer and an outermost topcoat, in which the single imageable layer comprises:

a radically polymerizable component,

an initiator composition capable of generating free radicals sufficient to initiate polymerization of free radically polymerizable groups upon exposure to imaging infrared radiation,

a polymeric binder, and

a radiation absorbing compound that can be an infrared radiation absorbing dye.

Useful imageable layer compositions and details of their preparation and use are provided in the following patent, publication, and copending patent applications, all of which are incorporated herein by reference:

U.S. Pat. No. 7,452,638 (Yu et al.),

U.S. Patent Application Publication 2008/0254387 (Yu et al.),

U.S. Ser. No. 11/756,036 filed May 31, 2007 by Yu et al.,

U.S. Ser. No. 11/762,288 filed Jun. 13, 2007 by Yu et al.,

U.S. Ser. No. 12/104,544 filed Apr. 17, 2008 by Ray et al., and

U.S. Ser. No. 12/177,208 filed Jul. 22, 2008 by Yu et al.

In general, the negative-working lithographic printing plate precursors have a radiation-sensitive composition disposed on a suitable substrate to form an imageable layer. In many embodiments, the radiation-sensitive composition is infrared radiation-sensitive.

The radiation-sensitive composition (and imageable layer) includes one or more free radically polymerizable components, each of which contains one or more free radically polymerizable groups that can be polymerized using free radical initiation. For example, such free radically polymerizable components can contain one or more free radical polymerizable monomers or oligomers having one or more addition polymerizable ethylenically unsaturated groups, crosslinkable ethylenically unsaturated groups, ring-opening polymerizable groups, azido groups, aryldiazonium salt groups, aryldiazosulfonate groups, or a combination thereof. Similarly, crosslinkable polymers having such free radically polymerizable groups can also be used.

Suitable ethylenically unsaturated components that can be polymerized or crosslinked include ethylenically unsaturated polymerizable monomers that have one or more of the polymerizable groups, including unsaturated esters of alcohols, such as acrylate and methacrylate esters of polyols. Oligomers or prepolymers, such as urethane acrylates and methacrylates, epoxide acrylates and methacrylates, polyester acrylates and methacrylates, polyether acrylates and methacrylates, and unsaturated polyester resins can also be used. In some embodiments, the free radically polymerizable component comprises carboxy groups.

Useful free radically polymerizable components include free-radical polymerizable monomers or oligomers that comprise addition polymerizable ethylenically unsaturated groups including multiple acrylate and methacrylate groups and combinations thereof, or free-radical crosslinkable polymers. Free radically polymerizable compounds include those derived from urea urethane(meth)acrylates or urethane(meth)acrylates having multiple polymerizable groups. For example, a free radically polymerizable component can be prepared by reacting DESMODUR® N100 aliphatic polyisocyanate resin based on hexamethylene diisocyanate (Bayer Corp., Milford, Conn.) with hydroxyethyl acrylate and pentaerythritol triacrylate. Useful free radically polymerizable compounds include NK Ester A-DPH (dipentaerythritol hexaacrylate) that is available from Kowa American, and Sartomer 399 (dipentaerythritol pentaacrylate), Sartomer 355 (di-trimethylolpropane tetraacrylate), Sartomer 295 (pentaerythritol tetraacrylate), and Sartomer 415 [ethoxylated (20)trimethylolpropane triacrylate] that are available from Sartomer Company, Inc.

Numerous other free radically polymerizable components are known to those skilled in the art and are described in considerable literature including Photoreactive Polymers: The Science and Technology of Resists, A Reiser, Wiley, New York, 1989, pp. 102-177, by B. M. Monroe in Radiation Curing: Science and Technology, S. P. Pappas, Ed., Plenum, New York, 1992, pp. 399-440, and in “Polymer Imaging” by A. B. Cohen and P. Walker, in Imaging Processes and Material, J. M. Sturge et al. (Eds.), Van Nostrand Reinhold, New York, 1989, pp. 226-262. For example, useful free radically polymerizable components are also described in EP 1,182,033A1 (noted above), beginning with paragraph [0170], and in U.S. Pat. No. 6,309,792 (Hauck et al.), U.S. Pat. No. 6,569,603 (Furukawa), and U.S. Pat. No. 6,893,797 (Munnelly et al.).

Other useful free radically polymerizable components include those described in copending and commonly assigned U.S. Ser. No. 11/949,810 (filed Dec. 4, 2007 by Bauman, Dwars, Strehmel, Simpson, Savariar-Hauck, and Hauck) that include 1H-tetrazole groups. This copending application is incorporated herein by reference.

In addition to, or in place of the free radically polymerizable components described above, the radiation-sensitive composition may include polymeric materials that include side chains attached to the backbone, which side chains include one or more free radically polymerizable groups (such as ethylenically unsaturated groups) that can be polymerized (crosslinked) in response to free radicals produced by the initiator composition (described below). There may be at least two of these side chains per molecule. The free radically polymerizable groups (or ethylenically unsaturated groups) can be part of aliphatic or aromatic acrylate side chains attached to the polymeric backbone. Generally, there are at least 2 and up to 20 such groups per molecule, or typically from 2 to 10 such groups per molecule.

Such free radically polymerizable polymers can also comprise hydrophilic groups including but not limited to, carboxy, sulfo, or phospho groups, either attached directly to the backbone or attached as part of side chains other than the free radically polymerizable side chains.

Useful commercial products that comprise polymers that can be used in this manner include Bayhydrol® UV VP LS 2280, Bayhydrol® UV VP LS 2282, Bayhydrol® UV VP LS 2317, Bayhydrol® UV VP LS 2348, and Bayhydrol® UV XP 2420, that are all available from Bayer MaterialScience, as well as Laromer™ LR 8949, Laromer™ LR 8983, and Laromer™ LR 9005, that are all available from BASF.

The one or more free radically polymerizable components (monomeric, oligomeric, or polymeric) can be present in the imageable layer in an amount of at least 10 weight % and up to 80 weight %, and typically from about 20 to about 50 weight %, based on the total dry weight of the imageable layer. The weight ratio of the free radically polymerizable component to the total polymeric binders (described below) is generally from about 5:95 to about 95:5, and typically from about 10:90 to about 90:10, or even from about 30:70 to about 70:30.

The radiation-sensitive composition also includes an initiator composition that includes one or more initiators that are capable of generating free radicals sufficient to initiate polymerization of all the various free radically polymerizable components upon exposure of the composition to imaging radiation. The initiator composition is generally responsive to imaging radiation corresponding to the spectral range of from about 250 to about 450 nm or of at least 700 nm and up to and including 1400 nm (typically from about 750 to about 1250 nm). Initiator compositions are used that are appropriate for the desired imaging wavelength(s).

For example, initiator composition can be responsive to UV (or violet) imaging radiation corresponding to the spectral range of at least 250 nm and up to and including 450 nm (typically from about 300 to about 475 nm). Initiator compositions are used that are appropriate for the desired imaging wavelength(s).

Useful initiators compositions include but are not limited to, one or more compounds chosen from any of the following classes of compounds (A) through (H) described below, or one or more compounds from multiple classes of compounds:

(A) Metallocenes are organometallic compounds having one or more cyclopentadienyl ligands that are optionally substituted at one or all of the ring carbons. Each carbon in the five-member ligand ring is coordinated to the transition metal center. Metallocenes are known for having a wide variety of transition metals including iron, titanium, tungsten, molybdenum, nickel, cobalt, chromium, zirconium, and manganese.

(B) Azines, for example, as described for example in U.S. Pat. No. 6,936,384 (Munnelly et al.). These compounds are organic heterocyclic compounds containing a 6-membered ring formed from carbon and nitrogen atoms. Azine compounds include heterocyclic groups such as pyridine, diazine, and triazine groups, as well as polycyclic compounds having a pyridine, diazine, or triazine substituent fused to one or more aromatic rings such as carbocyclic aromatic rings. Thus, the azine compounds include, for example, compounds having a quinoline, isoquinoline, benzodiazine, or naphthodiazine substituent. Both monocyclic and polycyclic azine compounds are useful.

Halomethyl-substituted triazines, such as trihalomethyl triazines, are useful in the initiator composition. Representative compounds of this type include but are not limited to, 1,3,5-triazine derivatives such as those having 1 to 3-CX₃ groups wherein X independently represent chlorine or bromine atoms, including polyhalomethyl-substituted triazines and other triazines, such as 2,4-trichloromethyl-6-methoxyphenyl triazine, 2-phenyl-4,6-bis(trichloromethyl)-s-triazine, 2,4,6-tris(trichloromethyl)-s-triazine, 2-methyl-4,6-bis(trichloromethyl)-s-triazine, 2-(styryl-4,6-bis(trichloromethyl)-s-triazine, 2-(p-methoxystyryl)-4,6-bis(trichloromethyl)-s-triazine, 2-(4-methoxy-naphtho-1-yl)-4,6-bis(trichloromethyl)-s-triazine, 2-(4-ethoxynaphtho-lyl)-4,6-bis(trichloromethyl)-s-triazine, and 2-(4-(2-ethoxyethyl)-naphtho-1-yl)-4,6-bis(trichloromethyl)-s-triazine], 2-(4-methylthiophenyl)-4,6-bis(trichloromethyl)-2-triazine, 2-(4-chlorophenyl-4,6-bis(trichloromethyl)-2-triazine, 2,4,6-tri(trichloromethyl)-2-triazine, and 2,4,6-tri(tribromomethyl)-2-triazine.

(C) Peroxides such as benzoyl peroxide and hydroperoxides such as cumyl hydroperoxide and other organic peroxides described for example in EP 1,035,435 (Sorori et al.).

(D) 2,4,5-Triarylimidazolyl dimers (also known as hexaarylbiimidazoles, or “HABI's”) as described for example in U.S. Pat. No. 4,565,769 (Dueber et al.). Examples of such compounds include but are not limited to, 2,2′-bis(o-chlorophenyl)-4,4′,5,5′-tetraphenylbiimidazole and 2,2′-bis(o-chlorophenyl)-4,4′5,5′-tetra(m-methoxyphenyl)biimidazole. Other useful “HABI's” are described by formula (V) and the listed examples on pages 25-27 of WO 07/090550 (Strehmel et al.) that is incorporated herein by reference for the disclosure of these compounds.

(E) Onium salts such as ammonium, iodonium, sulfonium salts, phosphonium, oxylsulfoxonium, oxysulfonium, diazonium, selenonium, arsenonium, and pyridinium salts. Useful iodonium salts are well known in the art and include but not limited to, U.S. Patent Application Publication 2002/0068241 (Oohashi et al.), WO 2004/101280 (Munnelly et al.), and U.S. Pat. No. 5,086,086 (Brown-Wensley et al.), U.S. Pat. No. 5,965,319 (Kobayashi), and U.S. Pat. No. 6,051,366 (Baumann et al.). For example, suitable phosphonium salts include positive-charged hypervalent phosphorus atoms with four organic substituents. Suitable sulfonium salts such as triphenylsulfonium salts include a positively-charged hypervalent sulfur with three organic substituents. Suitable diazonium salts possess a positive-charged azo group (that is —N═N⁺). Suitable ammonium salts include a positively-charged nitrogen atom such as substituted quaternary ammonium salts with four organic substituents, and quaternary nitrogen heterocyclic rings such as N-alkoxypyridinium salts. Suitable halonium salts include a positively-charged hypervalent halogen atom with two organic substituents. The onium salts generally include a suitable number of negatively-charged counterions such as halides, hexafluorophosphate, thiosulfate, hexafluoroantimonate, tetrafluoroborate, sulfonates, hydroxide, perchlorate, n-butyltriphenyl borate, tetraphenyl borate, and others readily apparent to one skilled in the art. Halonium salts are useful onium salts.

(F) Oxime esters or oxime ethers such as those derived from benzoin.

(G) N-phenyl glycine and derivatives thereof including compounds that have additional carboxy groups and can be considered polycarboxylic acids or anilino diacetic acids. Examples of such compounds include but are not limited to, N-phenylglycine and the glycine derivatives described in [0054] of WO 03/066338 (Timpe et al.).

(H) Thiol compounds such as heterocyclic mercapto compounds including mercaptotriazoles, mercaptobenzimidazoles, mercaptooxadiazoles, methcaptotetrazines, mercaptoimidazoles, mercaptopyridines, mercaptooxazoles, mercaptobenzoxazoles, mercaptobenzothiazoles, mercaptobenzoxadiazoles, mercaptotetrazoles, such as those described for example in U.S. Pat. No. 6,884,568 (Timpe et al.).

In some embodiments, useful initiator compositions include a combination of a 2,4,5-triarylimidazolyl dimer and a thiol compound, such as either 2,2′-bis(o-chlorophenyl)-4,4′,5,5′-tetraphenylbiimidazole or 2,2′-bis(o-chlorophenyl)-4,4′5,5′-tetra(m-methoxyphenyl)biimidazole in combination with a thiol compound such as a mercaptotriazole.

Other useful initiator compositions can include an onium salt such as an iodonium salt as described above in combination with a metallocene (for example a titanocene or ferrocene) as described for example in U.S. Pat. No. 6,936,384 (noted above).

Still other initiator compositions are responsive to radiation in the near-IR and IR regions, for example from about 700 to about 1400 nm. For example, useful iodonium cations are well known in the art including but not limited to, U.S. Patent Application Publication 2002/0068241 (Oohashi et al.), WO 2004/101280 (Munnelly et al.), and U.S. Pat. No. 5,086,086 (Brown-Wensley et al.), U.S. Pat. No. 5,965,319 (Kobayashi), and U.S. Pat. No. 6,051,366 (Baumann et al.). For example, a useful iodonium cation includes a positively charged iodonium, (4-methylphenyl)[4-(2-methylpropyl)phenyl]-moiety and a suitable negatively charged counterion. A representative example of such an iodonium salt is available as Irgacure® 250 from Ciba Specialty Chemicals (Tarrytown, N.Y.) that is (4-methylphenyl)[4-(2-methylpropyl)phenyl]iodonium hexafluorophosphate and is supplied in a 75% propylene carbonate solution.

Thus, the iodonium cations can be supplied as part of one or more iodonium salts, and as described below, the iodonium cations can be supplied as iodonium borates also containing suitable boron-containing anions. For example, the iodonium cations and the boron-containing anions can be supplied as part of salts that are combinations of Structures (IB) and (IBz) described below, or both the iodonium cations and boron-containing anions can be supplied from different sources. However, if they are supplied at least from the iodonium borate salts, since such salts generally supply about a 1:1 molar ratio of iodonium cations to boron-containing anions, additional iodonium cations must be supplied from other sources, for example, from iodonium salts described above.

One class of useful iodonium cations include diaryliodonium cations that are represented by the following Structure (IB):

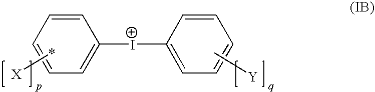

wherein X and Y are independently halo groups (for example, fluoro, chloro, or bromo), substituted or unsubstituted alkyl groups having 1 to 20 carbon atoms (for example, methyl, chloromethyl, ethyl, 2-methoxyethyl, n-propyl, isopropyl, isobutyl, n-butyl, t-butyl, all branched and linear pentyl groups, 1-ethylpentyl, 4-methylpentyl, all hexyl isomers, all octyl isomers, benzyl, 4-methoxybenzyl, p-methylbenzyl, all dodecyl isomers, all icosyl isomers, and substituted or unsubstituted mono- and poly-, branched and linear haloalkyls), substituted or unsubstituted alkyloxy having 1 to 20 carbon atoms (for example, substituted or unsubstituted methoxy, ethoxy, isopropoxy, t-butoxy, (2-hydroxytetradecyl)oxy, and various other linear and branched alkyleneoxyalkoxy groups), substituted or unsubstituted aryl groups having 6 or 10 carbon atoms in the carbocyclic aromatic ring (such as substituted or unsubstituted phenyl and naphthyl groups including mono- and polyhalophenyl and naphthyl groups), or substituted or unsubstituted cycloalkyl groups having 3 to 8 carbon atoms in the ring structure (for example, substituted or unsubstituted cyclopropyl, cyclopentyl, cyclohexyl, 4-methylcyclohexyl, and cyclooctyl groups). Typically, X and Y are independently substituted or unsubstituted alkyl groups having 1 to 8 carbon atoms, alkyloxy groups having 1 to 8 carbon atoms, or cycloalkyl groups having 5 or 6 carbon atoms in the ring, and more preferably, X and Y are independently substituted or unsubstituted alkyl groups having 3 to 6 carbon atoms (and particularly branched alkyl groups having 3 to 6 carbon atoms). Thus, X and Y can be the same or different groups, the various X groups can be the same or different groups, and the various Y groups can be the same or different groups. Both “symmetric” and “asymmetric” diaryliodonium borate compounds are contemplated but the “symmetric” compounds are preferred (that is, they have the same groups on both phenyl rings).

In addition, two or more adjacent X or Y groups can be combined to form a fused carbocyclic or heterocyclic ring with the respective phenyl groups.

The X and Y groups can be in any position on the phenyl rings but typically they are at the 2- or 4-positions on either or both phenyl rings.

Despite what type of X and Y groups are present in the iodonium cation, the sum of the carbon atoms in the X and Y substituents generally is at least 6, and typically at least 8, and up to 40 carbon atoms. Thus, in some compounds, one or more X groups can comprise at least 6 carbon atoms, and Y does not exist (q is 0). Alternatively, one or more Y groups can comprise at least 6 carbon atoms, and X does not exist (p is 0). Moreover, one or more X groups can comprise less than 6 carbon atoms and one or more Y groups can comprise less than 6 carbon atoms as long as the sum of the carbon atoms in both X and Y is at least 6. Still again, there may be a total of at least 6 carbon atoms on both phenyl rings.

In Structure IB, p and q are independently 0 or integers of 1 to 5, provided that either p or q is at least 1. Typically, both p and q are at least 1, or each of p and q is 1. Thus, it is understood that the carbon atoms in the phenyl rings that are not substituted by X or Y groups have a hydrogen atom at those ring positions.

Useful boron-containing anions are organic anions having four organic groups attached to the boron atom. Such organic anions can be aliphatic, aromatic, heterocyclic, or a combination of any of these. Generally, the organic groups are substituted or unsubstituted aliphatic or carbocyclic aromatic groups. For example, useful boron-containing anions can be represented by the following Structure (IBz):

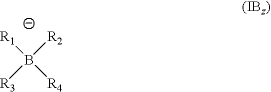

wherein R₁, R₂, R₃, and R₄ are independently substituted or unsubstituted alkyl groups having 1 to 12 carbon atoms (such as methyl, ethyl, n-propyl, isopropyl, n-butyl, isobutyl, t-butyl, all pentyl isomers, 2-methylpentyl, all hexyl isomers, 2-ethylhexyl, all octyl isomers, 2,4,4-trimethylpentyl, all nonyl isomers, all decyl isomers, all undecyl isomers, all dodecyl isomers, methoxymethyl, and benzyl) other than fluoroalkyl groups, substituted or unsubstituted carbocyclic aryl groups having 6 to 10 carbon atoms in the aromatic ring (such as phenyl, p-methylphenyl, 2,4-methoxyphenyl, naphthyl, and pentafluorophenyl groups), substituted or unsubstituted alkenyl groups having 2 to 12 carbon atoms (such as ethenyl, 2-methylethenyl, allyl, vinylbenzyl, acryloyl, and crotonotyl groups), substituted or unsubstituted alkynyl groups having 2 to 12 carbon atoms (such as ethynyl, 2-methylethynyl, and 2,3-propynyl groups), substituted or unsubstituted cycloalkyl groups having 3 to 8 carbon atoms in the ring structure (such as cyclopropyl, cyclopentyl, cyclohexyl, 4-methylcyclohexyl, and cyclooctyl groups), or substituted or unsubstituted heterocyclyl groups having 5 to 10 carbon, oxygen, sulfur, and nitrogen atoms (including both aromatic and non-aromatic groups, such as substituted or unsubstituted pyridyl, pyrimidyl, furanyl, pyrrolyl, imidazolyl, triazolyl, tetrazoylyl, indolyl, quinolinyl, oxadiazolyl, and benzoxazolyl groups). Alternatively, two or more of R₁, R₂, R₃, and R₄ can be joined together to form a heterocyclic ring with the boron atom, such rings having up to 7 carbon, nitrogen, oxygen, or nitrogen atoms. None of the R₁ through R₄ groups contains halogen atoms and particularly fluorine atoms.

Typically, R₁, R₂, R₃, and R₄ are independently substituted or unsubstituted alkyl or aryl groups as defined above, and more typically, at least 3 of R₁, R₂, R₃, and R₄ are the same or different substituted or unsubstituted aryl groups (such as substituted or unsubstituted phenyl groups). For example, all of R₁, R₂, R₃, and R₄ can be the same or different substituted or unsubstituted aryl groups, or all of the groups are the same substituted or unsubstituted phenyl group. Z⁻ can be a tetraphenyl borate wherein the phenyl groups are substituted or unsubstituted (for example, all are unsubstituted phenyl groups).

The iodonium cations and boron-containing anions are generally present in the imageable layer in a combined amount of at least 1% and up to and including 15%, and typically at least 4 and up to and including about 10%, based on total dry weight of the imageable layer.

The radiation-sensitive composition (and imageable element) generally includes one or more imaging radiation absorbing chromophores, or sensitizers, that spectrally sensitize the composition to a wavelength of from about 300 nm and up to and including 500 nm, typically from about 350 to about 475 nm, and more typically from about 390 to about 430 nm.

Useful sensitizers include but are not limited to, certain pyrilium and thiopyrilium dyes and 3-ketocoumarins. Some other useful sensitizers for such spectral sensitivity are described for example, in U.S. Pat. No. 6,908,726 (Korionoff et al.), WO 2004/074929 (Baumann et al.) that describes useful bisoxazole derivatives and analogues, and U.S. Patent Application Publications 2006/0063101 and 2006/0234155 (both Baumann et al.).

Still other useful sensitizers are the oligomeric or polymeric compounds having Structure (I) units defined in WO 2006/053689 (Strehmel et al.) that have a suitable aromatic or heteroaromatic unit that provides a conjugated π-system between two heteroatoms.

Additional useful “violet”-visible radiation sensitizers are the compounds described in WO 2004/074929 (Baumann et al.). These compounds comprise the same or different aromatic heterocyclic groups connected with a spacer moiety that comprises at least one carbon-carbon double bond that is conjugated to the aromatic heterocyclic groups, and are represented in more detail by Formula (I) of the noted publication.

Other useful sensitizers are the 2,4,5-triaryloxazole derivatives as described in WO 2004/074930 (Baumann et al.). These compounds can be used alone or with a co-initiator as described above.

EP 684,522 (Baumann et al.) describes radiation-sensitive compositions and imageable elements containing one or more dyes that have a spectral absorption in the range of from about 250 nm to about 700 nm.

The UV sensitizer can be present in the radiation-sensitive composition in an amount generally of at least 1% and up to and including 30% and typically at least 3 and up to and including 20%. The particular amount needed for this purpose would be readily apparent to one skilled in the art, depending upon the specific compound used to provide the desired chromophore.

Useful IR radiation absorbing chromophores include various IR-sensitive dyes (“IR dyes”). Examples of suitable IR dyes comprising the desired chromophore include but are not limited to, azo dyes, squarilium dyes, croconate dyes, triarylamine dyes, thioazolium dyes, indolium dyes, oxonol dyes, oxaxolium dyes, cyanine dyes, merocyanine dyes, phthalocyanine dyes, indocyanine dyes, indotricarbocyanine dyes, oxatricarbocyanine dyes, thiocyanine dyes, thiatricarbocyanine dyes, merocyanine dyes, cryptocyanine dyes, naphthalocyanine dyes, polyaniline dyes, polypyrrole dyes, polythiophene dyes, chalcogenopyryloarylidene and bi(chalcogenopyrylo)polymethine dyes, oxyindolizine dyes, pyrylium dyes, pyrazoline azo dyes, oxazine dyes, naphthoquinone dyes, anthraquinone dyes, quinoneimine dyes, methine dyes, arylmethine dyes, squarine dyes, oxazole dyes, croconine dyes, porphyrin dyes, and any substituted or ionic form of the preceding dye classes. Suitable dyes are also described in U.S. Pat. No. 5,208,135 (Patel et al.), U.S. Pat. No. 6,153,356 (Urano et al.), U.S. Pat. No. 6,264,920 (Achilefu et al.), U.S. Pat. No. 6,309,792 (Hauck et al.), and U.S. Pat. No. 6,787,281 (Tao et al.), and EP 1,182,033A2 (noted above). Infrared radiation absorbing N-alkylsulfate cyanine dyes are described for example in U.S. Pat. No. 7,018,775 (Tao).

A general description of one class of suitable cyanine dyes is shown by the formula in paragraph [0026] of WO 2004/101280 (Munnelly et al.), incorporated herein by reference, and a useful IR absorbing compound is identified below in the Examples.

In addition to low molecular weight IR-absorbing dyes, IR dye chromophores bonded to polymers can be used as well. Moreover, IR dye cations can be used as well, that is, the cation is the IR absorbing portion of the dye salt that ionically interacts with a polymer comprising carboxy, sulfo, phospho, or phosphono groups in the side chains.

Near infrared absorbing cyanine dyes are also useful and are described for example in U.S. Pat. No. 6,309,792 (Hauck et al.), U.S. Pat. No. 6,264,920 (Achilefu et al.), U.S. Pat. No. 6,153,356 (Urano et al.), U.S. Pat. No. 5,496,903 (Watanabe et al.). Suitable dyes may be formed using conventional methods and starting materials or obtained from various commercial sources including American Dye Source (Baie D'Urfe, Quebec, Canada) and FEW Chemicals (Germany). Other useful dyes for near infrared diode laser beams are described, for example, in U.S. Pat. No. 4,973,572 (DeBoer).

Some useful infrared radiation absorbing dyes have a tetraaryl pentadiene chromophore. Such chromophores generally include a pentadiene linking group having 5 carbon atoms in the chain, to which are attached two substituted or unsubstituted aryl groups at each end of the linking group. The pentadiene linking group can also be substituted with one or more substituents in place of the hydrogen atoms, or two or more hydrogen atoms can be replaced with atoms to form a ring in the linking group as long as there are alternative carbon-carbon single bonds and carbon-carbon double bonds in the chain.

Such IR-sensitive dyes can be represented by the following Structure DYE-II:

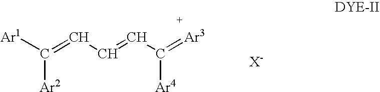

wherein Ar¹ through Ar⁴ are the same or different substituted or unsubstituted aryl groups having at least carbon atoms in the aromatic ring (such as phenyl, naphthyl, and anthryl, or other aromatic fused ring systems) wherein 1 to 3 of the aryl groups are substituted with the same or different tertiary amino group (such as in the 4-position of a phenyl group). Typically two of the aryl groups are substituted with the same or different tertiary amino group, and usually at different ends of the polymethine chain (that is, molecule). For example, Ar¹ or Ar² and Ar³ or Ar⁴ bear the tertiary amine groups. Representative amino groups include but are not limited to those substituted with substituted or unsubstituted alkyl groups having up to 10 carbon atoms or aryl groups such as dialkylamino groups (such as dimethylamino and diethylamino), diarylamino groups (such as diphenylamino), alkylarylamino groups (such as N-methylanilino), and heterocyclic groups such as pyrrolidino, morpholino, and piperidino groups. The tertiary amino group can form part of a fused ring such that one or more of Ar¹ through Ar⁴ can represent a julolidine group.

Besides the noted tertiary groups noted above, the aryl groups can be substituted with one or more substituted or unsubstituted alkyl groups having 1 to 10 carbon atoms, halo atoms (such as chloro or bromo), hydroxyl groups, thioether groups, and substituted or unsubstituted alkoxy groups having 1 to 10 carbon atoms. Substituents that contribute electron density to the conjugated system are useful. While they are not specifically shown in Structure (DYE-II), substituents or fused rings may also exist on (or as part of) the conjugated chain connecting the aryl groups.

In Structure (DYE-II), X⁻ is a suitable counterion that may be derived from a strong acid, and include such anions as ClO₄⁻, BF₄⁻, CF₃SO₃⁻, PF₆⁻, AsF₆⁻, SbF₆⁻, and perfluoroethylcyclohexylsulfonate. Other cations include boron-containing anions as described above (borates), methylbenzenesulfonic acid, benzenesulfonic acid, methanesulfonic acid, p-hydroxybenzenesulfonic acid, p-chlorobenzenesulfonic acid, and halides.

Useful infrared radiation absorbing dyes can be obtained from a number of commercial sources including Showa Denko (Japan) or they can be prepared using known starting materials and procedures.

Still other useful infrared radiation absorbing compounds are copolymers can comprise covalently attached ammonium, sulfonium, phosphonium, or iodonium cations and infrared radiation absorbing cyanine anions that have two or four sulfonate or sulfate groups, or infrared radiation absorbing oxonol anions, as described for example in U.S. Pat. No. 7,049,046 (Tao et al.).

The infrared radiation absorbing compounds can be present in the IR-sensitive composition (or imageable layer) in an amount generally of at least 1% and up to and including 30% and typically at least 3 and up to and including 20%, based on total solids in the composition, that also corresponds to the total dry weight of the imageable layer. The particular amount needed for this purpose would be readily apparent to one skilled in the art, depending upon the specific compound used to provide the desired chromophore.

The imageable layer includes one or more primary polymeric binders that are usually (but not always) present in the form of discrete particles having an average particle size of from about 10 to about 500 nm, and typically from about 150 to about 450 nm, and generally distributed uniformly within that layer. The particulate polymeric binders exist at room temperature as discrete particles, for example in an aqueous dispersion. However, the particles can also be partially coalesced or deformed, for example at temperatures used for drying coated imageable layer formulations. Even in this environment, the particulate structure is not destroyed. Such polymeric binders generally have a molecular weight (Mₙ) of at least 30,000 and typically at least 50,000 to about 100,000, or from about 60,000 to about 80,000, as determined by refractive index.

Other useful polymeric binders include but are not limited to, (meth)acrylic acid and acid ester resins [such as (meth)acrylates], polyvinyl acetals, phenolic resins, polymers derived from one or more (meth)acrylates, (meth)acrylonitriles, styrene, N-substituted cyclic imides or maleic anhydrides, including those described in EP 1,182,033 (Fujimaki et al.) and U.S. Pat. No. 6,309,792 (Hauck et al.), U.S. Pat. No. 6,352,812 (Shimazu et al.), U.S. Pat. No. 6,569,603 (Furukawa et al.), and U.S. Pat. No. 6,893,797 (Munnelly et al.). Also useful are the vinyl carbazole polymers described in U.S. Pat. No. 7,175,949 (Tao et al.), and the polymers having pendant vinyl groups as described in U.S. Pat. No. 7,279,255 (Tao et al.). Copolymers of polyethylene glycol methacrylate/acrylonitrile/styrene in particulate form, dissolved copolymers of carboxyphenyl methacrylamide/acrylonitrile/methacrylamide/N-phenyl maleimide, copolymers of polyethylene glycol methacrylate/acrylonitrile/-vinylcarbazole/styrene/methylacrylic acid, N-phenyl maleimide/-methacrylamide/methacrylic acid, urethane-acrylic intermediate A (the reaction product of p-toluene sulfonyl isocyanate and hydroxyl ethyl methacrylate)/-acrylonitrile/N-phenyl maleimide, and N-methoxymethyl methacrylamide/-methacrylic acid/acrylonitrile/n-phenylmaleimide are also useful.

The radiation-sensitive composition (imageable layer) can further comprise one or more phosphate(meth)acrylates, each of which has a molecular weight generally greater than 200 and typically at least 300 and up to and including 1000. By “phosphate(meth)acrylate” we also mean to include “phosphate methacrylates” and other derivatives having substituents on the vinyl group in the acrylate moiety. Such compounds and their use in imageable layers are described in more detail in U.S. Pat. No. 7,175,969 (Ray et al.) that is incorporated herein by reference.

Additional additives to the imageable layer include color developers or acidic compounds. As color developers, we mean to include monomeric phenolic compounds, organic acids or metal salts thereof, oxybenzoic acid esters, acid clays, and other compounds described for example in U.S. Patent Application Publication 2005/0170282 (Inno et al.).

The imageable layer can also include a variety of optional compounds including but not limited to, dispersing agents, humectants, biocides, plasticizers, surfactants for coatability or other properties, viscosity builders, pH adjusters, drying agents, defoamers, preservatives, antioxidants, development aids, rheology modifiers or combinations thereof, or any other addenda commonly used in the lithographic art, in conventional amounts. Useful viscosity builders include hydroxypropyl cellulose, hydroxyethyl cellulose, carboxymethyl cellulose, and poly(vinyl pyrrolidones).

### Imageable Elements

The imageable elements can be formed by suitable application of a radiation-sensitive composition as described above to a suitable substrate to form an imageable layer. This substrate can be treated or coated in various ways as described below prior to application of the radiation-sensitive composition to improve hydrophilicity. Typically, there is only a single imageable layer comprising the radiation-sensitive composition.

The element include what is conventionally known as an overcoat (such as an oxygen impermeable topcoat) applied to and disposed over the imageable layer for example, as described in WO 99/06890 (Pappas et al.). Such overcoat layers comprise one or more hydrophilic or water-soluble polymers such as a poly(vinyl alcohol), poly(vinyl pyrrolidone), poly(ethyleneimine), or poly(vinyl imidazole), copolymers of two or more of vinyl pyrrolidone, ethyleneimine, and vinyl imidazole in an amount of at least 50 weight % (or at least 90 weight %) based on total topcoat dry weight. The topcoat generally has a dry coating weight of at less than 1 g/m² in which the water-soluble polymer(s) comprise at least 90% and up to 100% of the dry weight of the overcoat. In many embodiments, the dry coating weight is less than 0.8 g/m² or even 0.5 g/m² or less. A poly(vinyl alcohol) can be the predominant polymeric binder (at least 50 weight % of total binders).

The topcoat can include particles dispersed throughout the hydrophilic polymer(s) if desired. Such particles can have an average diameter of from about 1 to about 6 μm and be polymeric or inorganic in nature. For example, useful particles include silica particles.

The substrate generally has a hydrophilic surface, or at least a surface that is more hydrophilic than the applied radiation-sensitive composition on the imaging side. The substrate comprises a support that can be composed of any material that is conventionally used to prepare imageable elements such as lithographic printing plates. It is usually in the form of a sheet, film, or foil (or web), and is strong, stable, and flexible and resistant to dimensional change under conditions of use. Typically, the support can be any self-supporting aluminum-containing material including aluminum sheets.

One useful substrate is composed of an aluminum support that may be treated using techniques known in the art, including roughening of some type by physical (mechanical) graining, electrochemical graining, or chemical graining, usually followed by acid anodizing. The aluminum support can be roughened by physical or electrochemical graining and then anodized using phosphoric or sulfuric acid and conventional procedures. A useful substrate is an electrochemically grained and phosphoric acid anodized aluminum support that provides a hydrophilic surface for lithographic printing.

An interlayer may be formed by treatment of the aluminum support with, for example, a silicate, dextrine, calcium zirconium fluoride, hexafluorosilicic acid, poly(vinyl phosphonic acid) (PVPA), vinyl phosphonic acid copolymer, poly[(meth)acrylic acid], poly(acrylic acid), or an acrylic acid copolymer to increase hydrophilicity. Still further, the aluminum support may be treated with a phosphate solution that may further contain an inorganic fluoride (PF). The aluminum support can be electrochemically-grained, phosphoric acid-anodized, and treated with poly(acrylic acid) using known procedures to improve surface hydrophilicity.

There are no polymer coatings on the backside (non-imaging side) of the aluminum-containing substrate, and the average surface roughness (Ra) in both the longitudinal and width of the backside is greater than 0.15 μm as measured using a MicroXAM instrument (available from KPA-Tencor, San Jose, Calif.).

The thickness of the substrate can be varied but should be sufficient to sustain the wear from printing and thin enough to wrap around a printing form. Useful embodiments include a treated aluminum foil having a thickness of at least 100 μm and up to and including 700 μm.

The substrate can also be a cylindrical aluminum surface having the radiation-sensitive composition applied thereon, and thus be an integral part of the printing press. The use of such imaging cylinders is described for example in U.S. Pat. No. 5,713,287 (Gelbart).

The radiation-sensitive composition can be applied to the substrate as a solution or dispersion in a coating liquid using any suitable equipment and procedure, such as spin coating, knife coating, gravure coating, die coating, slot coating, bar coating, wire rod coating, roller coating, or extrusion hopper coating. The composition can also be applied by spraying onto a suitable support (such as an on-press printing cylinder). Typically, the radiation-sensitive composition is applied and dried to form an imageable layer and an overcoat formulation is applied to that layer.

Illustrative of such manufacturing methods is mixing the radically polymerizable component, primary polymeric binder, initiator composition, radiation absorbing compound, and any other components of the radiation-sensitive composition in a suitable organic solvent or mixtures thereof [such as methyl ethyl ketone (2-butanone), methanol, ethanol, 1-methoxy-2-propanol, iso-propyl alcohol, acetone, γ-butyrolactone, n-propanol, tetrahydrofuran, and others readily known in the art, as well as mixtures thereof], applying the resulting solution to a substrate, and removing the solvent(s) by evaporation under suitable drying conditions. Some representative coating solvents and imageable layer formulations are described in the Examples below. After proper drying, the coating weight of the imageable layer is generally at least 0.1 and up to and including 5 g/m² or at least 0.5 and up to and including 3.5 g/m².

Layers can also be present under the imageable layer to enhance developability or to act as a thermal insulating layer. The underlying layer should be soluble or at least dispersible in the developer and typically have a relatively low thermal conductivity coefficient.

The various layers may be applied by conventional extrusion coating methods from melt mixtures of the respective layer compositions. Typically such melt mixtures contain no volatile organic solvents.

Intermediate drying steps may be used between applications of the various layer formulations to remove solvent(s) before coating other formulations. Drying steps at conventional times and temperatures may also help in preventing the mixing of the various layers.

Once the various layers have been applied and dried on the substrate, the imageable element can be enclosed in water-impermeable material that substantially inhibits the transfer of moisture to and from the imageable element as described in U.S. Pat. No. 7,175,969 (noted above) that is incorporated herein by reference.

Imaging and development of the negative-working lithographic printing plate precursors would be readily known to a worker of ordinary skill in the art.

In many embodiments of the invention, the stack has from 20 to 1000 negative-working lithographic printing plate precursors, or at least 100 of them, or more likely at least 250 of the precursors.

In some embodiments of the present invention, the stack includes from 20 to 800 of negative-working lithographic printing plate precursors, wherein each single imageable layer of each precursor comprises:

a radically polymerizable component,

an initiator composition capable of generating free radicals sufficient to initiate polymerization of free radically polymerizable groups upon exposure to imaging infrared radiation,

a polymeric binder, and

a infrared radiation absorbing dye, and

a topcoat that has a dry coating weight less than 0.8 g/m² and that comprises a poly(vinyl alcohol).

The following examples are provided to illustrate the practice of this invention and not to be limiting in any manner.

### EXAMPLES

The imageable layer and topcoat formulations shown below in TABLE I were coated onto an electrochemically-grained and sulfuric acid anodized aluminum substrate that had been post-treated with monosodium phosphate/sodium fluoride. The formulations were applied to give dry coating weights of 1.2 g/m² for the imageable layer and 0.4 g/m² for the topcoat using a slotted-hopper and then dried for approximately 20 seconds at 265° F. (129° C.) for the imageable layer and 255° F. (124° C.) for the topcoat.

TABLE I

| | Coating Level |
|---|---|
| Imageable Layer | |
| Hybridur ® 580 | 2.85 |
| Polymer A | 0.85 |
| NK-Ester A-DPH | 1.29 |
| Sartomer SR-399 | 1.29 |
| IB-05 | 0.46 |
| S 0507 IR Dye | 0.13 |
| Sipomer PAM 100 | 0.26 |
| Pigment 951 | 1.32 |
| FluorN ™ 2900 | 0.50 |
| PGME | 24.46 |
| Methyl Ethyl Ketone | 34.95 |
| Water | 6.67 |
| Methanol | 14.12 |
| 4-Butyrolactone | 11.30 |
| Topcoat | |
| PVA-403 | 1.48 |
| Masurf ® 1520 | 0.007 |
| Water | 94.57 |
| 2-Propanol | 3.94 |

Hybridur® 580 is a urethane-acrylic hybrid polymer dispersion (40%) that was obtained from Air Products and Chemicals, Inc. (Allentown, Pa.).

Polymer A: Carboxyphenyl methacrylamide/acrylonitrile/-methacrylamide/N-phenyl maleimide at 37/48/10/5 by wt. %, acid no.=97.8 (binder-solvent resistant).

NK Ester A-DPH is a dipentaerythritol hexaacrylate that was obtained from Kowa American (New York, N.Y.).

Sartomer SR399 is dipentaerythritol pentaacrylate that was obtained from Sartomer Company, Inc. (Exton, Pa.).

Sipomer PAM-100 is a phosphate functional specialty monomer and was obtained from Rhodia Inc. (Cranbury, N.J.).

IB05 represents bis(4-t-butylphenyl) iodonium tetraphenylborate.

Pigment 951 is a 27% solids dispersion of 7.7 parts of a polyvinyl acetal derived from poly(vinyl alcohol) acetalized with acetaldehyde, butyraldehyde, and 4-formylbenzoic acid, 76.9 parts of Irgalith Blue GLVO (Cu-phthalocyanine C.I. Pigment Blue 15:4), and 15.4 parts of Disperbyk® 167 dispersant (Byk Chemie) in 1-methoxy-2-propanol.

S0507 is an IR dye that is available from FEW GmbH (Wolfen, Del.).

FluorN™ 2900 is a polyperfluoroether-based fluorourethane glycol surfactant that was obtained from Cytonix (Beltsville, Md.).

PGME represents 1-methoxy-2-propanol and it is also known as Dowanol PM.

PVA-403 is a poly vinyl alcohol available from Kuraray (New York, N.Y.).

Masurf® FS-1520 is a fluoroaliphatic betaine fluorosurfactant that was obtained from Mason Chemical Company (Arlington Heights, Ill.).

Where used, interleaf (slip-sheet) paper was 30# Kraft XKL that was obtained from Thilmany (Kaukauna, Wis.).

Approximately 1000 linear meters were coated in the experiment. Short sections, approximately 70 linear meters, were cut into plates of 1030×800 mm dimension. One section included slip-sheet paper between cut plates, and sections that had no interleaf (slip-sheet) paper were run on two different production lines. The following tests were performed on plates with and without interleaf (slip-sheet) paper:

1) Visual assessment of coat and cut plates with a 25× loupe.

2) Assessment of imageable elements imaged using a Kodak® Trendsetter 3244 and processed through a Kodak Mercury mark VI charged with SP200 developer held at 23° C. with a throughput speed of 5 ft/min (1.5 m/min). The imageable elements were imaged with an imaging energy density of 65 mJ/cm². They were imaged with solid patterns as well as 50% line screen at a resolution of 200 lpi.

3) Element samples were fed through an auto-loader image setter: Kodak Trendsetter News & Kodak 800II Quantum, and then assessed as in 1) & 2) above.

Following all assessments, no difference could be distinguished between the elements with and without interleaf (slip-sheet) paper.

Top-coat film weight variation- the imageable layer formulation of the production line experiment was applied to a 0.3 mm gauge aluminum sheet, electro-grained, anodized and subject to treatment with monosodium phosphate/sodium fluoride on the imaging side using a 0.006 inch (0.015 cm) wire-wound bar to provide a dry coating weight of approximately 1.20 g/m². This coating was dried for 35 seconds at 120° C. After drying, the topcoat solution was applied in a similar manner to yield a range of dry coating weights and dried in the same manner as the imageable layer. The topcoat film weights tested were 0.4, 0.8, 1.0, 1.2, and 1.6 g/m².

The robustness of the coating was assessed using a cross-cut tape test with a tester supplied by Precision Gage and Tooling Company (Dayton, Ohio). This test was carried out in accordance with ASTM D-3359.

It was observed that an increase of topcoat film weight was detrimental to the coating integrity and this became particularly a problem when it was greater than 1.0 g/m². The ratings for the coatings as per ASTM D-3359 are shown in the following TABLE II.

TABLE II

| Topcoat Coating (g/m²) | Rating | Comments |
|---|---|---|
| 0.4 | 5B | no effect |
| 0.8 | 3B | removal at edge |
| 1.0 | 3B | removal at edge |
| 1.2 | 2B | significant adhesion loss |
| 1.6 | 2B | significant adhesion loss |

An aging test was conducted in which the plate samples were subjected to 1.05 Kg/cm (15 psi) pressure and held at a temperature of 48° C. for 3 days. Plate samples with and without interleaf paper (slip-sheet) were tested. The slip-sheet was difficult to remove from the plate samples with topcoat film weights of 1.2 and 1.6 g/m² (somewhat sticking to the topcoat) while the slip-sheet was easily removed from plate samples with topcoat film weights of 0.4 and 0.8 g/m².

After removing the plate samples from the pressure/aging, a tape pull test was done on the cross-cut areas of the plate samples (ASTM D-3359). When comparing plate samples with and without slip-sheet, there were no large differences seen between plate samples of the same coating weight, but there were differences between the different coating weights. The thicker topcoats resulted in removal of the base layer during the tape pull test.

It was observed that after pressure and aging, the plate sample with a topcoat coating weight of 0.4 g/m² had no damage, the plate sample with a topcoat coating weight of 0.8 g/m² had slight damage, and those with higher topcoat weights (over 1 g/m²) had considerable damage.

The invention has been described in detail with particular reference to certain preferred embodiments thereof, but it will be understood that variations and modifications can be effected within the spirit and scope of the invention.

1. A stack comprising a plurality of negative-working lithographic printing plate precursors wherein each precursor comprises an aluminum-containing substrate having thereon a single imageable layer and an outermost topcoat that has a dry coating weight equal to or less than 1 g/m²,
wherein the non-imaging backside of said substrate is free of polymer coatings and has an average surface roughness (Ra) in both longitudinal and width directions greater than 0.15 μm and wherein the imageable side of each underlying precursor is arranged in direct contact with the aluminum-containing substrate of the precursor above it, without the use of an interleaf paper between said precursors.

2. The stack of claim 1 comprising at least 100 negative-working lithographic printing plate precursors.

3. The stack of claim 1 wherein the dry coating weight of said outermost topcoat is equal to or less than 0.8 g/m².

4. The stack of claim 1 wherein the dry coating weight of said outermost topcoat is equal to or less than 0.5 g/m².

5. The stack of claim 1 wherein said outermost topcoat comprises one or more hydrophilic polymers in an amount of at least 50 weight %, based on topcoat dry weight.

6. The stack of claim 1 wherein said outermost topcoat comprises one or more hydrophilic polymers in an amount of at least 90 weight %, based on topcoat dry weight.

7. The stack of claim 1 wherein said outermost topcoat comprises a poly(vinyl alcohol) as its predominant polymeric binder.

8. The stack of claim 1 wherein each of said lithographic printing plate precursors is sensitive to imaging radiation of from about 250 to about 450 nm.

9. The stack of claim 1 wherein each of said lithographic printing plate precursors is sensitive to imaging radiation of from about 700 to about 1400 nm.

10. The stack of claim 1 wherein each of said lithographic printing plate precursors is on-press developable.

11. The stack of claim 1 wherein said outermost topcoat comprises particles having an average diameter of from about 1 to about 6 μm.

12. The stack of claim 11 wherein said outermost topcoat particles comprise silica.

13. The stack of claim 1 wherein said single imageable layer comprises:
a radically polymerizable component,
an initiator composition capable of generating free radicals sufficient to initiate polymerization of free radically polymerizable groups upon exposure to imaging infrared radiation,
a polymeric binder, and
a radiation absorbing compound.

14. The stack of claim 13 wherein said radiation absorbing compound is an infrared radiation absorbing dye.

15. The stack of claim 13 wherein said polymeric binder has a backbone to which are attached pendant poly(alkylene oxide) side chains, cyano groups, or both, and is optionally present in the form of discrete particles.

16. The stack of claim 1 comprising from 20 to 800 of said precursors, wherein said single imageable layer of each precursor comprises:
a radically polymerizable component,
an initiator composition capable of generating free radicals sufficient to initiate polymerization of free radically polymerizable groups upon exposure to imaging infrared radiation,
a polymeric binder, and
a infrared radiation absorbing dye, and
a topcoat that has a dry coating weight less than 0.8 g/m² and that comprises a poly(vinyl alcohol).
